(19) United States
(12) Patent Application Publication
(10) Pub. No.: US 2016/0365504 A1
(43) Pub. Date: Dec. 15, 2016

(54) PIEZOELECTRIC THIN FILM ELEMENT, METHOD FOR MANUFACTURING THE SAME, AND ELECTRONIC DEVICE INCLUDING PIEZOELECTRIC THIN FILM ELEMENT

(71) Applicant: Hitachi Metals, Ltd., Tokyo (JP)

(72) Inventors: Kazufumi Suenaga, Tsuchiura (JP); Kenji Shibata, Tsukuba (JP); Kazutoshi Watanabe, Tsuchiura (JP); Fumimasa Horikiri, Nagareyama (JP); Masaki Noguchi, Tsuchiura (JP)

(21) Appl. No.: 14/466,833

(22) Filed: Aug. 22, 2014

(30) Foreign Application Priority Data
Aug. 29, 2013 (JP) 2013-178025

(51) Int. Cl. H01L 41/297; H01L 41/187; H01L 41/332; H01L 41/047

(52) U.S. Cl. CPC H01L 41/297; H01L 41/0471; H01L 41/1873; H01L 41/332

(57) ABSTRACT

A method for manufacturing an alkali-niobate-based piezoelectric thin film element includes a lower-electrode-film forming step of forming a lower electrode film on a substrate; a piezoelectric-thin-film forming step of forming an alkali-niobate-based piezoelectric thin film on the lower electrode film; an etching-mask-pattern forming step of forming a desired pattern of an etching mask on the piezoelectric thin film; and a piezoelectric-thin-film etching step of dry-etching the piezoelectric thin film into a desired pattern. The etching mask is made of an oxide at least in a layer adjacent to the piezoelectric thin film.

The present application is based on Japanese patent application No. 2013-178025 filed on Aug. 29, 2013, the entire contents of which are incorporated herein by reference.

### BACKGROUND OF THE INVENTION

1. Field of the Invention

The present invention relates to piezoelectric thin film elements, and particularly to thin film elements that use lead-free alkali-niobate-based piezoelectric materials and methods for manufacturing such piezoelectric thin film elements. The present invention also relates to electronic devices including such piezoelectric thin film elements.

2. Description of the Related Art

Piezoelectric elements operate by the piezoelectric effect of a piezoelectric material. Piezoelectric elements have been widely used as functional electronic components such as actuators, which produce a displacement or vibration in response to a voltage applied to the piezoelectric material, and stress sensors, which produce a voltage in response to a strain applied to the piezoelectric material. In particular, lead-zirconate-titanate-based perovskite-type ferroelectric materials (the formula Pb(Zr₁₋ₓTiₓ)O₃, PZT) have been widely used in actuators and stress sensors because of their high piezoelectric performance.

PZT, which is a specified hazardous substance containing lead, has been exempted from the RoHS directive (the directive on the restriction of the use of certain hazardous substances in electrical and electronic equipment) because no suitable alternative has been available on the market. However, the growing worldwide awareness of global environmental protection is driving the need for the development of piezoelectric elements that use piezoelectric materials containing no lead (lead-free piezoelectric materials). In addition, the growing need for more compact and lightweight electronic devices is increasing the need for piezoelectric thin film elements manufactured by a thin film technology.

An example piezoelectric thin film element that uses a lead-free piezoelectric material is disclosed in Japanese Unexamined Patent Application Publication No. 2007-19302 (Patent Literature 1). This piezoelectric element includes a substrate having thereon a lower electrode, a piezoelectric thin film, and an upper electrode. The piezoelectric thin film is a dielectric thin film made of an alkali-niobate-based perovskite-type compound represented by the formula (NaₓK_{y}Li_{z})NbO₃ (where 0<x<1, 0<y<1, 0≦z<1, and x+y+z=1). A buffer layer is disposed between the piezoelectric thin film and the lower electrode. The buffer layer is a thin film of a material that has a perovskite-type crystal structure and that is readily oriented with a high degree of orientation in the (001), (100), (010), or (111) plane. Patent Literature 1 teaches that this piezoelectric thin film element, which uses a lead-free sodium potassium lithium niobate thin film, provides sufficient piezoelectric performance.

A piezoelectric element basically includes a piezoelectric thin film disposed between a pair of electrodes and is formed in a beam or fork pattern, depending on the application, by microfabrication. Microfabrication is one of the important technologies for the commercialization of piezoelectric elements that use lead-free piezoelectric materials.

For example, Japanese Unexamined Patent Application Publication No. 2012-33693 (Patent Literature 2) discloses a method for manufacturing a piezoelectric thin film wafer. This method includes a first step of etching a piezoelectric thin film (the formula (K₁₋ₓNaₓ)NbO₃ (where 0.4≦x≦0.7)) on a wafer by ion etching with a gas containing argon and a second step of etching the piezoelectric thin film by reactive ion etching with an etching gas mixture of a fluorine-containing reactive gas and argon. Patent Literature 2 teaches that this method allows high-precision microfabrication on piezoelectric thin films and thus provides reliable piezoelectric thin film elements and inexpensive piezoelectric thin film devices.

Chan Min Kang, Gwan-Ha Kim, Kyoung-Tae Kim, and Chang-Il Kim, “Etching Characteristics of (Na_{0.5}K_{0.5})NbO₃ Thin Films in an Inductively Coupled Cl₂/Ar Plasma”, Ferroelectrics, 357, 179-184 (2007) (Non-Patent Literature 1) reports research on the etching characteristics of (Na_{0.5}K_{0.5})NbO₃ with an inductively coupled plasma in a gas mixture of chlorine and argon. Non-Patent Literature 1 reports that the etching rate of (Na_{0.5}K_{0.5})NbO₃ increased monotonically with the power supplied to generate the inductively coupled plasma and the negative direct-current bias, as expected from changes in various plasma parameters. Non-Patent Literature 1 also reports that the etching rate of (Na_{0.5}K_{0.5})NbO₃ did not change monotonically with the mixing ratio of chlorine to argon, but a maximum etching rate of 75 nm/min was achieved in a chlorine-to-argon ratio of 80/20. Non-Patent Literature 1 concludes that this etching rate is due to the combination of the chemical and physical paths in the ion-assisted chemical reaction.

### SUMMARY OF THE INVENTION

As described above, alkali-niobate-based piezoelectric materials (e.g., sodium potassium lithium niobate (NaₓK_{y}Li_{z})NbO₃)) are one of the promising lead-free piezoelectric materials. For commercialization and mass production of thin film elements that use alkali-niobate-based piezoelectric materials as an alternative to PZT thin film elements, it is important to establish a low-cost, reliable microfabrication process with high dimensional precision.

However, microfabrication processes on alkali-niobate-based piezoelectric materials, which are a relatively new group of materials, are still at the trial-and-error stage. For example, if the dry etching process disclosed in Patent Literature 2 is performed at a higher etching rate for improved productivity, it may damage the remaining piezoelectric thin film and therefore degrade the piezoelectric properties thereof because of some factors. This may decrease the manufacturing yield.

Non-Patent Literature 1, which reports research on the mechanism by which a (Na_{0.5}K_{0.5})NbO₃ thin film is etched during dry etching, does not discuss its relationship with the piezoelectric properties of the thin film.

One disadvantage of piezoelectric thin film elements is that even damage to part of the surface of a piezoelectric thin film during microfabrication significantly affects the overall piezoelectric properties because the piezoelectric material, which forms the basis of their function, has a small absolute volume and a large surface area. As described above, only limited knowledge is available about microfabrication processes on alkali-niobate-based piezoelectric materials because they are a relatively new group of materials, and the factors for degraded properties are also yet to be understood. Thus, no effective solution has been found.

Accordingly, it is a primary object of the present invention to provide a method for manufacturing a thin film element that uses a lead-free alkali-niobate-based piezoelectric material by microfabrication without degrading the piezoelectric properties thereof. It is another object of the present invention to provide a piezoelectric thin film element manufactured by such a method and an electronic device including such a piezoelectric thin film element.

(I) To achieve the above objects, an aspect of the present invention provides a method for manufacturing an alkali-niobate-based piezoelectric thin film element. This method includes a lower-electrode-film forming step of forming a lower electrode film on a substrate; a piezoelectric-thin-film forming step of forming a piezoelectric thin film on the lower electrode film; an etching-mask-pattern forming step of forming a desired pattern of an etching mask on the piezoelectric thin film; and a piezoelectric-thin-film etching step of dry-etching the piezoelectric thin film into a desired pattern. The piezoelectric thin film is made of an alkali-niobate-based piezoelectric material represented by the formula (NaₓK_{y}Li_{z})NbO₃, where 0≦x≦1, 0≦y 1, 0≦z≦0.2, and x+y+z=1. The etching mask is made of an oxide at least in a layer adjacent to the piezoelectric thin film.

The following improvements and modifications may be made to the above method for manufacturing an alkali-niobate-based piezoelectric thin film element:

(i) The oxide may be silicon oxide.

(ii) The etching mask may have a multilayer structure including the layer made of the oxide and a layer made of an oxide different from the oxide.

(iii) The different oxide may be aluminum oxide.

(iv) The etching mask may have a multilayer structure including the layer made of the oxide and a layer made of a metal.

(v) The metal may be chromium.

(vi) The dry etching may be reactive ion etching.

(vii) The lower electrode film may be made of platinum.

(viii) The piezoelectric thin film may have a pseudocubic crystal structure, may be formed by sputtering, and may have a main surface preferentially oriented in a (001) plane.

(ix) The substrate may be a silicon substrate having a thermally oxidized film thereon.

(x) The method may further include an upper-electrode-film forming step of forming an upper electrode film on the desired pattern of the piezoelectric thin film; and a dicing step of dicing the substrate having thereon the piezoelectric thin film and the upper electrode film into a piezoelectric thin film element chip.

(II) To achieve the above objects, another aspect of the present invention provides an alkali-niobate-based piezoelectric thin film element manufactured by the above method for manufacturing an alkali-niobate-based piezoelectric thin film element. The dielectric loss tangent of the alkali-niobate-based piezoelectric thin film after the piezoelectric-thin-film etching step is 1.2 times or less the dielectric loss tangent of the alkali-niobate-based piezoelectric thin film before the piezoelectric-thin-film etching step. The leakage current density of the alkali-niobate-based piezoelectric thin film after the piezoelectric-thin-film etching step is 10 times or less the leakage current density of the alkali-niobate-based piezoelectric thin film before the piezoelectric-thin-film etching step.

(III) To achieve the above objects, another aspect of the present invention provides an electronic device including the above alkali-niobate-based piezoelectric thin film element.

According to aspects of the present invention, it is possible to provide a method for manufacturing a thin film element that uses a lead-free alkali-niobate-based piezoelectric material by microfabrication without degrading the piezoelectric properties thereof. Thus, it is possible to provide a piezoelectric thin film element that maintains the high piezoelectric performance of an alkali-niobate-based piezoelectric material and an electronic device including such a piezoelectric thin film element.

### BRIEF DESCRIPTION OF THE DRAWINGS

The foregoing and other exemplary purposes, aspects and advantages will be better understood from the following detailed description of the invention with reference to the drawings, in which:

FIGS. 1A to 1D′ are schematic enlarged sectional views illustrating a process of manufacturing a piezoelectric-thin-film-deposited substrate according to an embodiment of the present invention (to an etching-mask forming step);

FIGS. 2A to 2B are schematic enlarged sectional views illustrating the process of manufacturing a piezoelectric-thin-film-deposited substrate according to the embodiment (piezoelectric-thin-film etching step);

FIGS. 3A to 3C are schematic enlarged sectional views illustrating a process of manufacturing a piezoelectric thin film element according to the embodiment (upper-electrode-film forming step and later);

FIG. 4 is a graph showing the relationship between the dielectric loss tangent and the thickness of a SiO₂ mask for a reference sample, Comparative Example 1, and Examples 1 to 4;

FIG. 5 is a graph showing the relationship between the leakage current density and the thickness of a SiO₂ mask for the reference sample, Comparative Example 1, and Examples 1 to 4;

FIG. 6 is a graph showing the relationship between the dielectric loss tangent and the applied voltage for Comparative Example 1 and Example 4; and

FIG. 7 is a graph showing the relationship between the polarization and the applied voltage for Comparative Example 1 and Example 4.

### DESCRIPTION OF THE PREFERRED EMBODIMENTS

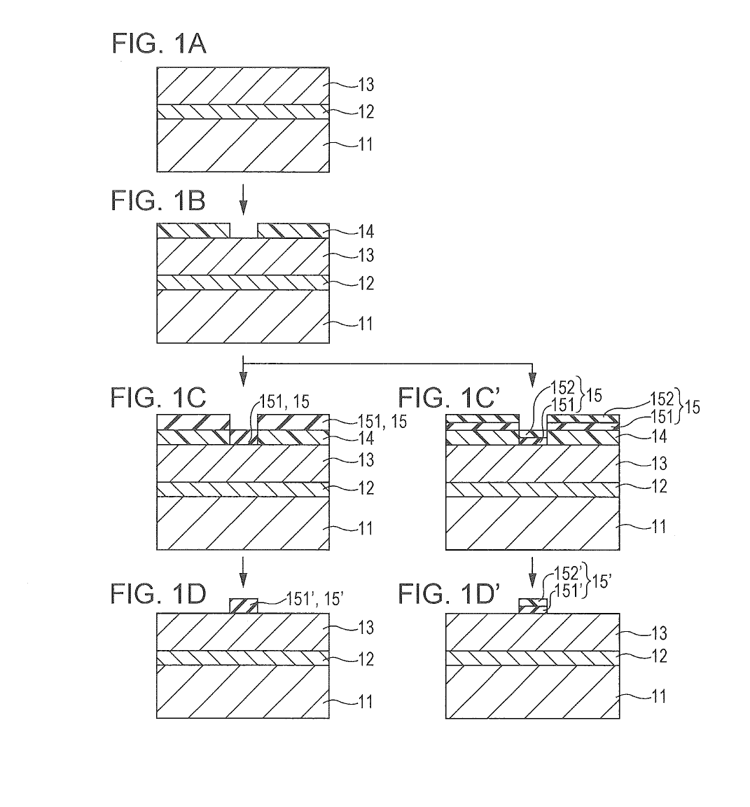

Referring now to the drawings, and more particularly to FIGS. 1-7, there are shown exemplary embodiments of the methods and structures according to the present invention.

The inventors have focused on alkali-niobate-based piezoelectric materials ((NaₓK_{y}Li_{z})NbO₃, NKLN), which are lead-free piezoelectric materials expected to provide a comparable piezoelectric performance to lead zirconate titanate (Pb(Zr₁₋ₓTiₓ)O₃, PZT), and have conducted extensive research on the dry etching of these materials.

In the related art, an alkali-niobate-based piezoelectric material is dry-etched through an etching mask made of a metal film, mainly for reasons of etching selectivity. The inventors have hypothesized that the degradation of the piezoelectric properties of a piezoelectric thin film during dry etching results from a loss of oxygen in the piezoelectric thin film due to a slight chemical reaction in the interface between the metal film used as the etching mask and the piezoelectric thin film during the etching. After further research, the inventors have found that the degradation of the piezoelectric properties of a piezoelectric thin film during dry etching can be significantly reduced if the etching mask is made of an oxide at least in the layer adjacent to the piezoelectric thin film. These findings have led to the present invention.

Embodiments of the present invention will now be described with reference to the drawings. The present invention, however, should not be construed as being limited to the embodiments discussed herein. Various combinations and improvements are possible without departing from the technical scope of the present invention.

FIGS. 1A to 1D′ are schematic enlarged sectional views illustrating a process of manufacturing a piezoelectric-thin-film-deposited substrate according to an embodiment of the present invention (to an etching-mask forming step). Although a cleaning step and a drying step are omitted in the following description, these steps are preferably performed if necessary.

A substrate 11 is provided first. The substrate 11 may be made of any material selected depending on the application of the piezoelectric element. Examples of such materials include silicon (Si), silicon-on-insulator (SOI) substrates, quartz glass, gallium arsenide (GaAs), sapphire (Al₂O₃), metals such as stainless steel, magnesium oxide (MgO), and strontium titanate (SrTiO₃). If the substrate 11 is made of a conductive material, it preferably has an electrically insulating film (e.g., an oxide film) formed thereon. The oxide film may be formed in any method, preferably by thermal oxidation or chemical vapor deposition (CVD).

### Lower-Electrode-Film Forming Step

In this step, a lower electrode film 12 is formed on the substrate 11 (see FIG. 1A). The lower electrode film 12 may be made of any material, preferably platinum (Pt) or a platinum-based alloy. The lower electrode film 12 may be formed in any method, for example, preferably by sputtering. The lower electrode film 12 preferably has an arithmetic mean surface roughness Ra of 0.86 nm or less so that the piezoelectric thin film described later provides sufficient piezoelectric performance.

### Piezoelectric-Thin-Film Forming Step

In this step, a piezoelectric thin film 13 is formed on the lower electrode film 12 (see FIG. 1A). The piezoelectric thin film 13 is preferably made of (NaₓK_{y}Li_{z})NbO₃ (NKLN, where 0≦x≦1, 0≦y≦1, 0≦z≦0.2, and x+y+z=1). The piezoelectric thin film 13 is preferably formed by sputtering or electron beam deposition with a sintered NKLN target. Sputtering and electron beam deposition are advantageous in terms of deposition reproducibility, deposition rate, and operating cost and also allow the orientation control of an NKLN crystal. For improved piezoelectric performance, the resulting piezoelectric thin film 13 preferably has a pseudocubic NKLN crystal structure and has a main surface preferentially oriented in the (001) plane.

The piezoelectric thin film 13 may contain impurities such as tantalum (Ta), antimony (Sb), calcium (Ca), copper (Cu), barium (Ba), and titanium (Ti) in a total amount of 5 atomic percent or less.

### Etching-Mask Forming Step

In this step, an etching mask for dry etching, described later, is formed on the deposited piezoelectric thin film 13. Specifically, a photoresist pattern 14 is formed on the piezoelectric thin film 13 by a photolithography process (see FIG. 1B).

An etching mask 15 is then deposited on the photoresist pattern 14. In this embodiment, the etching mask 15 is made of an oxide at least in the layer (first oxide layer 151) adjacent to the piezoelectric thin film 13 (see FIGS. 1C and 1C′). For reasons of ease of handling (e.g., deposition and removal) and cost, the first oxide layer 151 is preferably a silicon oxide layer (e.g., a SiO₂ layer). The first oxide layer 151 may be formed in any method, for example, by known processes such as sputtering, plasma-enhanced CVD, and spin-on-glass (SOG) technique.

As shown in FIG. 1C′, the etching mask 15 may have a multilayer structure including the first oxide layer 151 and a layer 152 different from the first oxide layer 151. In this case, the layer 152 different from the first oxide layer 151 is preferably made of a material that exhibits a higher etching selectivity than the first oxide layer 151 during dry etching, described later. For example, the layer 152 different from the first oxide layer 151 is preferably made of aluminum oxide (e.g., Al₂O₃) or a metal such as gold (Au), platinum, palladium (Pd), or chromium (Cr). The layer 152 different from the first oxide layer 151 may be formed in any method, for example, by known processes such as sputtering. Although FIG. 1C′ illustrates a two-layer structure, which is the simplest multilayer structure, the etching mask 15 may include three or more layers.

A desired etching mask pattern 15′ (patterned first oxide layer 151′ and layer 152′ different from the first oxide layer 151) is then formed by a lift-off process (see FIGS. 1D and 1D′). The etching mask pattern 15′ may also be formed by processes other than photolithography and lift-off.

### Piezoelectric-Thin-Film Etching Step

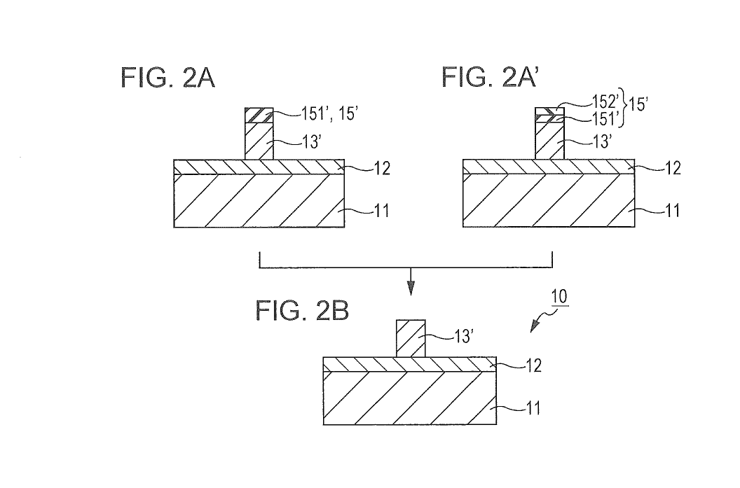

FIGS. 2A to 2B are schematic enlarged sectional views illustrating the process of manufacturing a piezoelectric-thin-film-deposited substrate according to this embodiment (piezoelectric-thin-film etching step). In this step, the piezoelectric thin film 13 is dry-etched into the pattern defined by the etching mask pattern 15′ (see FIGS. 2A and 2A′). The piezoelectric thin film 13 may be dry-etched in any method, preferably by inductively coupled plasma reactive ion etching (ICP-RIE). As the etching gas, it is preferred to use a noble gas (e.g., argon (Ar)) and a reactive gas (e.g., trifluoromethane (CHF₃), tetrafluoromethane (CF₄), hexafluoroethane (C₂F₆), octafluorocyclobutane (C₄F₈), or sulfur hexafluoride (SF₆)). Thus, a desired piezoelectric thin film pattern 13′ can be formed.

After dry etching, the first oxide layer 151 is removed with an etchant for silicon oxide (e.g., buffered hydrofluoric acid) to obtain a piezoelectric-thin-film-deposited substrate 10 having thereon a desired pattern of an NKLN piezoelectric thin film (see FIG. 2B).

### Upper-Electrode-Film Forming Step

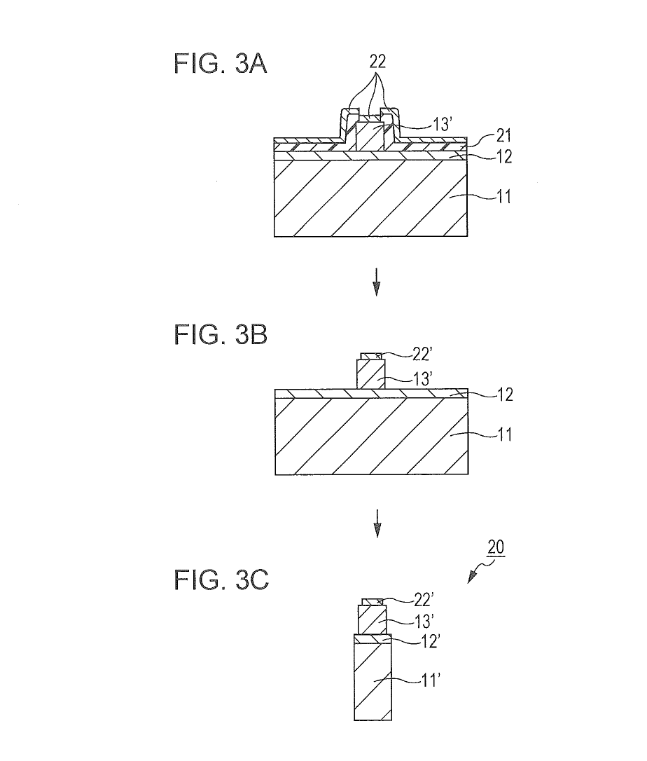

FIGS. 3A to 3C are schematic enlarged sectional views illustrating a process of manufacturing a piezoelectric thin film element according to this embodiment (upper-electrode-film forming step and later). In this step, an upper electrode film is formed on the desired pattern of the piezoelectric thin film (piezoelectric thin film pattern 13′) formed in the previous step. Specifically, a photoresist pattern 21 is formed in the region other than the region in which the upper electrode film is to be formed by a photolithography process, and an upper electrode film 22 is deposited on the photoresist pattern 21 (see FIG. 3A). The photoresist pattern 21 is then removed by a lift-off process to leave an upper electrode film 22′ (see FIG. 3B). The upper electrode film 22 (upper electrode film 22′) is preferably made of a material such as aluminum, gold, nickel (Ni), or platinum.

### Dicing Step

In this step, the substrate having formed thereon the piezoelectric thin film pattern 13′ and the upper electrode film 22′ is diced into a piezoelectric thin film element chip 20 (see FIG. 3C). The piezoelectric thin film element 20 includes a substrate chip 11′ and a lower electrode film 12′. Thus, a piezoelectric thin film element 20 including a desired pattern of a piezoelectric thin film can be fabricated.

### Electronic Device Including Piezoelectric Thin Film Element

The thus-fabricated piezoelectric thin film element 20 can be used to provide an environmentally friendly high-performance lead-free electronic component. Examples of electronic components include microsystem devices (e.g., micro-electro-mechanical system (MEMS) devices), stress/pressure sensors, actuators, and variable capacitors.

### EXAMPLES

The present invention is further illustrated by the following examples, although the present invention is not limited to these examples.

### Fabrication of Piezoelectric-Thin-Film-Deposited Substrate

Piezoelectric-thin-film-deposited substrates 10 having thereon a desired pattern of a piezoelectric thin film were fabricated by the manufacturing process illustrated in FIGS. 1A to 2B. The substrate 11 was a silicon substrate having thereon a thermally oxidized film (4 inch wafer oriented in the (100) plane, having a wafer thickness of 0.525 mm, and having thereon a thermally oxidized film with a thickness of 205 nm).

A titanium layer was deposited to a thickness of 2.3 nm on the silicon substrate by radio-frequency (RF) magnetron sputtering to form an adhesion layer for improving the adhesion between the substrate 11 and the lower electrode film 12. A platinum layer was then deposited to a thickness of 215 nm on the titanium layer by RF magnetron sputtering to form the lower electrode film 12 (see FIG. 1A). The adhesion layer and the lower electrode film 12 were deposited by sputtering with a pure titanium target and a pure platinum target, respectively, at a substrate temperature of 250° C., a discharge power of 200 W, and a pressure of 2.5 Pa in an argon atmosphere. The arithmetic mean surface roughness Ra of the deposited lower electrode film 12 was measured to be 0.86 nm or less.

A (Na_{0.65}K_{0.35})NbO₃ (hereinafter referred as “NKN”) thin film was then deposited to a thickness of 2 μm on the lower electrode film 12 by RF magnetron sputtering to form the piezoelectric thin film 13 (see FIG. 1A). The NKN thin film was deposited by sputtering with a sintered NKN target at a substrate temperature of 520° C., a discharge power of 700 W, and a pressure of 1.3 Pa in a mixed atmosphere of oxygen gas and argon gas (in a mixed ratio of O₂/Ar=0.005).

A photoresist (OFPR-800 from Tokyo Ohka Kogyo Co., Ltd.) was then applied, exposed, and developed on the NKN piezoelectric thin film to form the photoresist pattern 14 (see FIG. 1B). A SiO₂ film was then deposited to a thickness of 0.2 to 1.5 μm by RF magnetron sputtering to form the first oxide layer 151 (see FIG. 10). The SiO₂ film was deposited by sputtering with a quartz plate target at a substrate temperature of 25° C., a discharge power of 400 W, and a pressure of 0.7 Pa in a mixed atmosphere of oxygen gas and argon gas (in a mixed ratio of O₂/Ar=0.033).

For one sample, an Al₂O₃ film was deposited to a thickness of 0.2 μm on the first oxide layer 151 (with a thickness of 0.2 μm) by RF magnetron sputtering to form the layer 152 different from the first oxide layer 151 (see FIG. 1C′). The Al₂O₃ film was deposited by sputtering with a sintered alumina target at a substrate temperature of 25° C., a discharge power of 400 W, and a pressure of 0.7 Pa in a mixed atmosphere of oxygen gas and argon gas (in a mixed ratio of O₂/Ar=0.033).

For another sample, a chromium film was deposited to a thickness of 0.2 μm on the first oxide layer 151 (with a thickness of 0.2 μm) by RF magnetron sputtering to form the layer 152 different from the first oxide layer 151 (see FIG. 1C′). The chromium film was deposited by sputtering with a pure chromium target at a substrate temperature of 25° C., a discharge power of 50 W, and a pressure of 0.8 Pa in an argon atmosphere.

For a comparative sample, a chromium film was directly deposited to a thickness of 0.4 μm on the NKN piezoelectric thin film by RF magnetron sputtering (see FIG. 1C′). The chromium film was deposited by sputtering with a pure chromium target at a substrate temperature of 25° C., a discharge power of 50 W, and a pressure of 0.8 Pa in an argon atmosphere.

Thereafter, the photoresist pattern 14 was removed by cleaning with acetone (lift-off) to form the etching mask pattern 15′ on the NKN piezoelectric thin film (see FIGS. 1D and 1D′). The etching masks are listed in Table 1 below.

### Etching Test

The samples having different etching mask patterns were dry-etched in an ICP-RIE system (EIS-700 from Elionix Inc.) under the same etching conditions. The samples were etched at an antenna power of 800 W, a bias power of 100 W, and a pressure of 0.1 Pa using argon and C₄F₈ as the etching gas.

After the dry etching of the NKN piezoelectric thin film, the samples having the first oxide layer (SiO₂ layer) were etched with an etchant for SiO₂ (buffered hydrofluoric acid) to remove the etching mask, and the sample having the chromium mask alone (comparative sample) was etched with an etchant for chromium (ceric ammonium nitrate) to remove the etching mask.

### Fabrication of Piezoelectric Thin Film Element

The photoresist pattern 21 was formed on the NKN piezoelectric thin film on the thus-fabricated piezoelectric-thin-film-deposited substrate 10 by the manufacturing process illustrated in FIGS. 3A to 3C, and the upper electrode film 22 was deposited to a thickness of 200 nm by RF magnetron sputtering (see FIG. 3A). The upper electrode film 22 was deposited under the same conditions as the lower electrode film 12, i.e., by sputtering with a pure platinum target at a substrate temperature of 250° C., a discharge power of 200 W, and a pressure of 2.5 Pa in an argon atmosphere.

Thereafter, the photoresist pattern 21 was removed by cleaning with acetone (lift-off) to leave the upper electrode film 22′ on the NKN piezoelectric thin film (see FIG. 3B). The substrate 11 was then diced into NKN piezoelectric thin film element chips.

For a reference sample, the upper electrode film 22 was deposited to a thickness of 200 nm on an NKN piezoelectric thin film not patterned by dry etching. This sample was free from the influence of dry etching, serving as a reference for piezoelectric properties.

### Measurement and Evaluation of Piezoelectric Properties

The resulting NKN piezoelectric thin film elements were examined using a ferroelectric property evaluation system for their dielectric loss tangent (tan δ), leakage current density, and polarization. The measurements of the dielectric loss tangent (tan δ) and the leakage current density are shown in Table 1 together with the type of etching mask. The measurements of each sample are representative of measurements from 100 elements.

TABLE 1
Type of etching mask and measurements of piezoelectric properties

| | Etching mask for dry etching | | | | |
|---|---|---|---|---|---|
| | Thickness | Thickness | Thickness of | | Leakage |
| | of SiO₂ | of Al₂O₃ | chromium | | current |
| | film | film | film | | density |
| | (μm) | (μm) | (μm) | tanδ | (μA/cm²) |
| Reference | No dry etching | | | 0.20 | 0.94 |
| sample | | | | | |
| Comparative | — | — | 0.4 | 0.76 | 3,760 |
| Example 1 | | | | | |
| Example 1 | 0.2 | — | — | 0.22 | 5.1 |
| Example 2 | 0.5 | — | — | 0.19 | 1.6 |
| Example 3 | 1 | — | — | 0.21 | 3.5 |
| Example 4 | 1.5 | — | — | 0.21 | 0.1 |
| Example 5 | 0.2 | 0.2 | — | 0.19 | 1.4 |
| Example 6 | 0.2 | — | 0.2 | 0.20 | 1.5 |

As shown in Table 1, the reference sample, which was free from the influence of dry etching, exhibited a sufficiently low dielectric loss tangent (tan δ) and leakage current density. This demonstrates that the NKN piezoelectric thin film formed in the above examples was a high-quality piezoelectric thin film. In contrast, Comparative Example 1, which used a metal film etching mask in the related art, exhibited a dielectric loss tangent of nearly four times higher than that of the reference sample and a leakage current density of not less than three orders of magnitude higher than that of the reference sample. This demonstrates that the piezoelectric properties were noticeably degraded.

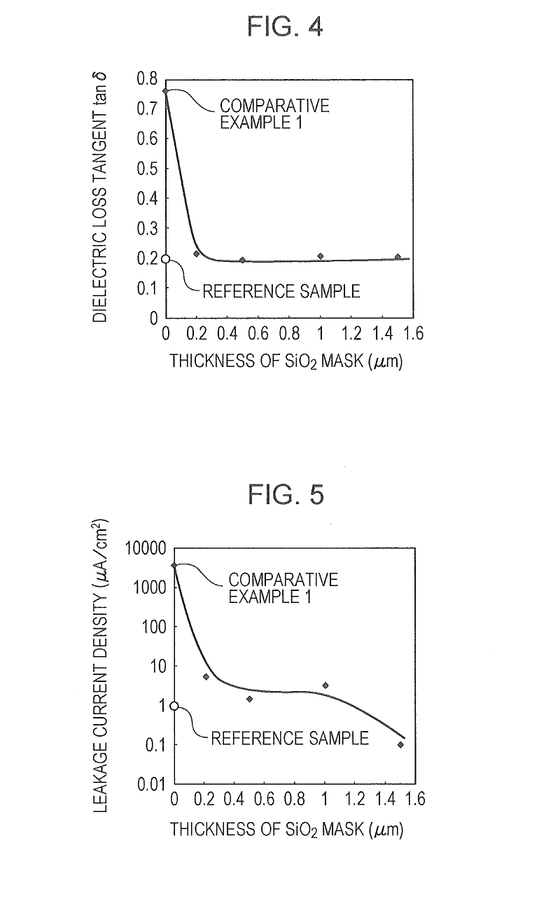

FIG. 4 is a graph showing the relationship between the dielectric loss tangent and the thickness of the SiO₂ mask for the reference sample, Comparative Example 1, and Examples 1 to 4. FIG. 5 is a graph showing the relationship between the leakage current density and the thickness of the SiO₂ mask for the reference sample, Comparative Example 1, and Examples 1 to 4. As can be seen from Table 1 and FIGS. 4 and 5, Examples 1 to 6, which are within the scope of the present invention, exhibited a dielectric loss tangent of about 1.1 times higher than that of the reference sample and a leakage current density of not more than one order of magnitude higher than that of the reference sample.

A dielectric loss tangent of 1.2 times or less that of the reference sample is acceptable. Leakage current densities that differ by one order of magnitude or less are assumed to be practically equal because the leakage current density often varies by orders of magnitude depending on the method of measurement. Thus, the results demonstrate that the piezoelectric properties of the NKN piezoelectric thin films of Examples 1 to 6 were not degraded by microfabrication.

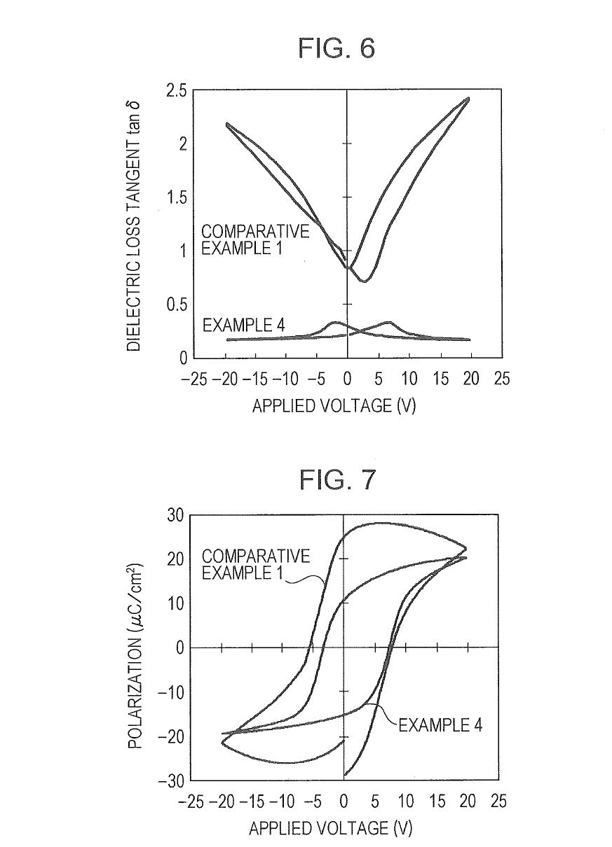

FIG. 6 is a graph showing the relationship between the dielectric loss tangent and the applied voltage for Comparative Example 1 and Example 4. As shown in FIG. 6, the dielectric loss tangent of Comparative Example 1 increased with increasing applied voltage, demonstrating that the dielectric properties were noticeably degraded. In contrast, the dielectric loss tangent of Example 4 remained nearly constant with increasing applied voltage and was low over the entire range of measurement voltage. This demonstrates that the dielectric properties of an NKN piezoelectric thin film according to an embodiment of present invention were not degraded by dry etching.

FIG. 7 is a graph showing the relationship between the polarization and the applied voltage for Comparative Example 1 and Example 4. As shown in FIG. 7, Comparative Example 1 showed an expanded and open polarization hysteresis loop, demonstrating that the ferroelectric properties were degraded. In contrast, Example 4 showed a narrow and properly closed polarization hysteresis loop. This demonstrates that the ferroelectric properties of an NKN piezoelectric thin film according to an embodiment of present invention were not degraded by dry etching.

As demonstrated above, according to embodiments of the present invention, it is possible to manufacture a thin film element that uses an alkali-niobate-based piezoelectric material by microfabrication without degrading the piezoelectric properties thereof. Thus, it is possible to provide a piezoelectric thin film element that maintains the high piezoelectric performance of an alkali-niobate-based piezoelectric material and an electronic device including such a piezoelectric thin film element.

The foregoing embodiments and examples have been described in order to assist in understanding the present invention. The present invention should not be construed as being limited to the specific configurations disclosed herein. For example, part of the configuration of a certain embodiment may be replaced with that of the configuration of another embodiment, or may be added to the configuration of another embodiment. Thus, part of the configurations of the embodiments and examples disclosed herein may be removed or replaced with that of another configuration, or may be added to another configuration.

What is claimed is:

1. A method for manufacturing an alkali-niobate-based piezoelectric thin film element, comprising:
a lower-electrode-film forming step of forming a lower electrode film on a substrate;
a piezoelectric-thin-film forming step of forming a piezoelectric thin film on the lower electrode film, the piezoelectric thin film comprising an alkali-niobate-based piezoelectric material represented by the formula (NaₓK_{y}Li_{z})NbO₃, where 0≦x≦1, 0≦y≦1, 0≦z≦0.2, and x+y+z=1;
an etching-mask-pattern forming step of forming a desired pattern of an etching mask on the piezoelectric thin film; and
a piezoelectric-thin-film etching step of dry-etching the piezoelectric thin film into a desired pattern,
wherein the etching mask comprises an oxide at least in a layer adjacent to the piezoelectric thin film.

2. The method for manufacturing an alkali-niobate-based piezoelectric thin film element according to claim 1, wherein the oxide is silicon oxide.

3. The method for manufacturing an alkali-niobate-based piezoelectric thin film element according to claim 1, wherein the etching mask has a multilayer structure including the layer comprising the oxide and a layer comprising an oxide different from the oxide.

4. The method for manufacturing an alkali-niobate-based piezoelectric thin film element according to claim 3, wherein the different oxide is aluminum oxide.

5. The method for manufacturing an alkali-niobate-based piezoelectric thin film element according to claim 1, wherein the etching mask has a multilayer structure including the layer comprising the oxide and a layer comprising a metal.

6. The method for manufacturing an alkali-niobate-based piezoelectric thin film element according to claim 5, wherein the metal is chromium.

7. The method for manufacturing an alkali-niobate-based piezoelectric thin film element according to claim 1, wherein the dry etching is reactive ion etching.

8. The method for manufacturing an alkali-niobate-based piezoelectric thin film element according to claim 1, wherein the lower electrode film comprises platinum.

9. The method for manufacturing an alkali-niobate-based piezoelectric thin film element according to claim 1, wherein the piezoelectric thin film has a pseudocubic crystal structure, is formed by sputtering, and has a main surface preferentially oriented in a (001) plane.

10. The method for manufacturing an alkali-niobate-based piezoelectric thin film element according to claim 1, wherein the substrate is a silicon substrate having a thermally oxidized film thereon.

11. The method for manufacturing an alkali-niobate-based piezoelectric thin film element according to claim 1, further comprising:
an upper-electrode-film forming step of forming an upper electrode film on the desired pattern of the piezoelectric thin film; and
a dicing step of dicing the substrate having thereon the piezoelectric thin film and the upper electrode film into a piezoelectric thin film element chip.

12. An alkali-niobate-based piezoelectric thin film element manufactured by the method for manufacturing an alkali-niobate-based piezoelectric thin film element according to claim 1, wherein
the dielectric loss tangent of the alkali-niobate-based piezoelectric thin film after the piezoelectric-thin-film etching step is 1.2 times or less the dielectric loss tangent of the alkali-niobate-based piezoelectric thin film before the piezoelectric-thin-film etching step, and
the leakage current density of the alkali-niobate-based piezoelectric thin film after the piezoelectric-thin-film etching step is 10 times or less the leakage current density of the alkali-niobate-based piezoelectric thin film before the piezoelectric-thin-film etching step.

13. An electronic device comprising the alkali-niobate-based piezoelectric thin film element according to claim 12.
